(19) United States
(12) Patent Application Publication
(10) Pub. No.: US 2025/0040408 A1
(43) Pub. Date: Jan. 30, 2025

(54) REINFORCING LAYER AND DISPLAY DEVICE INCLUDING THE SAME

(71) Applicant: Samsung Display Co., LTD., Yongin-si (KR)

(72) Inventors: JOOYOUNG KIM, Yongin-si (KR); YOUNG-JOO NAM, Yongin-si (KR); DOHYUN PARK, Yongin-si (KR); YOUNGJIN PARK, Yongin-si (KR)

(21) Appl. No.: 18/658,059

(22) Filed: May 8, 2024

(30) Foreign Application Priority Data
Jul. 24, 2023 (KR) 10-2023-0095863

(51) Int. Cl. H10K 59/80; H10K 59/90

(52) U.S. Cl. CPC H10K 59/873; H10K 59/90

(57) ABSTRACT

A display device includes an array substrate including a display area including pixels, a peripheral area and a pad area, in order in a first direction, driving chips on the array substrate, in the pad area, the driving chips arranged spaced apart from each other along a second direction intersecting the first direction, an encapsulation layer on the array substrate and covering the pixels, the encapsulation layer including a base portion overlapping the display area and the peripheral area, and convex portions protruding from a side of the base portion, in the first direction, the convex portions overlapping the pad area, and a cover member covering the driving chips, in the pad area, the cover member contacting the convex portions of the encapsulation layer.

This application claims priority to Korean Patent Application No. 10-2023-0095863, filed on Jul. 24, 2023, and all the benefits accruing therefrom under 35 U.S.C. § 119, which is hereby incorporated by reference for all purposes as if fully set forth herein.

### BACKGROUND

### 1. Field

Embodiments relate to a display device. More specifically, the embodiments relate to a display device

### 2. Description of the Related Art

The display device is an electronic device which displays an image for providing visual information to a user. Among display devices, an organic light emitting diode display has attracted attention.

In an electronic display device, a plurality of driving chips provide driving signals to a plurality of pixels for image display. Accordingly, each of the plurality of pixels emits light, where the emitted light is used for generating and/or displaying the image. The plurality of pixels and driving chips may be disposed inside the display device.

### SUMMARY

Embodiments provide a display device with improved durability.

A display device according to an embodiment may include an array substrate including a display area in which a plurality of pixels is arranged, a peripheral area surrounding the display area, and a pad area adjacent to the peripheral area and spaced from one side of the display area in a first direction, a plurality of driving chips disposed in the pad area on the array substrate and arranged in a row along a second direction intersecting the first direction, an encapsulation layer disposed on the array substrate, covering the pixels, including a base portion overlapping the display area and the peripheral area, and convex portions protruding from the base portion toward the pad area and overlapping the pad area, and a cover member covering the driving chips in the pad area and contacting the convex portions of the encapsulation layer.

In an embodiment, the driving chips and the convex portions may be spaced apart from each other on a plane.

In an embodiment, the driving chips, on a plane, may be all disposed within a single concave portion defined by the base portion and the convex portions.

In an embodiment, at least one of the convex portions may be located between the driving chips on a plane.

In an embodiment, the convex portions and the driving chips may be arranged alternately along the second direction on a plane.

In an embodiment, the convex portions may extend to an end of the array substrate which is furthest from the display area in the first direction.

In an embodiment, the cover member may contact the driving chips.

In an embodiment, the cover member may be spaced apart from an upper surface of the array substrate which is closest to the cover member, in a thickness direction of the array substrate.

In an embodiment, the display device may further include a reinforcing member disposed in a concave portion defined by the base portion and the convex portions in the pad area and contacting the cover member.

In an embodiment, the reinforcing member may be spaced apart from the driving chips on a plane.

In an embodiment, the reinforcing member may include first reinforcing members (e.g., first reinforcing patterns) spaced apart from each other in the first direction with at least one of the driving chips interposed therebetween.

In an embodiment, the reinforcing member may include second reinforcing members (e.g., second reinforcing patterns) spaced apart from each other in the second direction with at least one of the driving chips interposed therebetween.

In an embodiment, the reinforcing member may include an adhesive material.

In an embodiment, the display device may further include a flexible circuit film electrically connected to the array substrate, at a pad electrode of the array substrate, a circuit board electrically connected to the array substrate by the flexible circuit film, a cushion layer disposed under the array substrate and including an insulating material, and an electrified layer disposed under the cushion layer and including a conductive material, where the cover member covers at least one of the flexible circuit film and the circuit board.

A display device according to an embodiment may include an array substrate including a display area in which a plurality of pixels is arranged, a peripheral area surrounding the display area, and a pad area adjacent to the peripheral area and spaced from one side of the display area in a first direction, a plurality of driving chips disposed in the pad area on the array substrate and arranged in a row along a second direction intersecting the first direction, an encapsulation layer disposed on the array substrate, covering the pixels, a reinforcing member disposed in the pad area on the array substrate, and spaced apart from the driving chips and the encapsulation layer, and a cover member covering the driving chips in the pad area and contacting the reinforcing member.

In an embodiment, the reinforcing member may be spaced apart from the driving chips on a plane.

In an embodiment, the reinforcing member may include first reinforcing members spaced apart from each other in the first direction with at least one of the driving chips interposed therebetween.

In an embodiment, the reinforcing member may include second reinforcing members spaced apart from each other in the second direction with at least one of the driving chips interposed therebetween.

In an embodiment, the reinforcing member may include an adhesive material.

In an embodiment, the display device may further include a flexible circuit film electrically connected to a pad electrode of the array substrate, a circuit board electrically connected to the flexible circuit film, a cushion layer disposed under the array substrate and including an insulating material, and an electrified layer disposed under the cushion layer and including a conductive material, where the cover member covers at least one of the flexible circuit film and the circuit board.

The display device according to embodiments may include an encapsulation layer on an array substrate. The encapsulation layer may include a base portion overlapping a display area and a surrounding area thereof, and a convex portion protruding from a side of the base portion and toward the pad area. Accordingly, since a thickness of the display device increases at the pad area owing to the stacked structure including a reinforcing layer (e.g., the encapsulation layer at the convex portions and/or the reinforcing patterns), cracks occurring in the array substrate may be reduced or prevented. In addition, as the encapsulation layer includes the convex portion providing a surface area for contacting by the cover member, a contact surface (area) of a cover member within the pad area contacting the encapsulation layer may be expanded. Accordingly, a lifting phenomenon of the cover member relative to the stacked structure including the encapsulation layer may be reduced or prevented and durability of the display device may be improved.

In the display device according to embodiments, a reinforcing pattern within a reinforcing layer which is spaced apart from driving chips and the encapsulation layer may be disposed in the pad area of the array substrate. Accordingly, the cover member may contact the reinforcing pattern. Accordingly, a contact surface (area) where the cover member contacts other components within the stacked structure on the array substrate may be expanded. Accordingly, the lifting phenomenon of the cover member may be reduced or prevented and durability of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a plan view illustrating the display device of FIG. 1 with a cover member omitted.

FIG. 3 is an enlarged plan view of area A of FIG. 1.

FIG. 4 is a cross-sectional view taken along line I-I′ of FIG. 3.

FIG. 5 is a cross-sectional view taken along line II-II′ of FIG. 3.

FIG. 6 is a plan view illustrating an example of the display device of FIG. 1.

FIG. 7 is a cross-sectional view taken along line III-III′ of FIG. 6.

FIG. 8 is a cross-sectional view taken along line IV-IV′ of FIG. 6.

FIG. 9, FIG. 10, FIG. 11, and FIG. 12 are plan views respectively illustrating various examples of the display device of FIG. 1.

FIG. 13 is a plan view illustrating a display device according to an embodiment of present disclosure.

FIG. 14 is an enlarged plan view of area B of FIG. 13.

FIG. 15 is a cross-sectional view taken along line V-V′ of FIG. 14.

FIG. 16 is a cross-sectional view taken along line V-V′ of FIG. 14.

FIG. 17 is a plan view illustrating a display device according to an embodiment of present disclosure.

FIG. 18 is an enlarged plan view of area C of FIG. 17.

FIG. 19 is an enlarged cross-sectional view taken along line VI-VI′ of FIG. 18.

FIG. 20 is an enlarged cross-sectional view illustrating an example of a cross-section taken along line VI-VI′ of FIG. 18.

FIG. 21 is a plan view illustrating a display device according to an embodiment of present disclosure.

FIG. 22 is a plan view illustrating a display device according to an embodiment of present disclosure.

FIG. 23 is a plan view illustrating a display device according to an embodiment of present disclosure.

FIG. 24 is a plan view illustrating a display device according to an embodiment of present disclosure.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Within the Figures and the text of the disclosure, a reference number indicating a singular form of an element may also be used to reference a plurality of the singular element.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

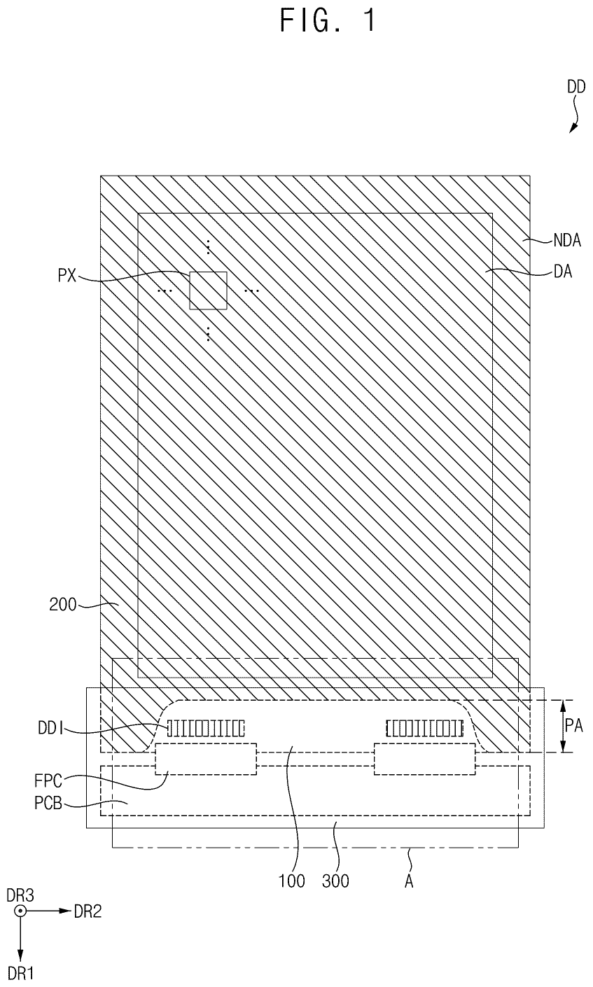

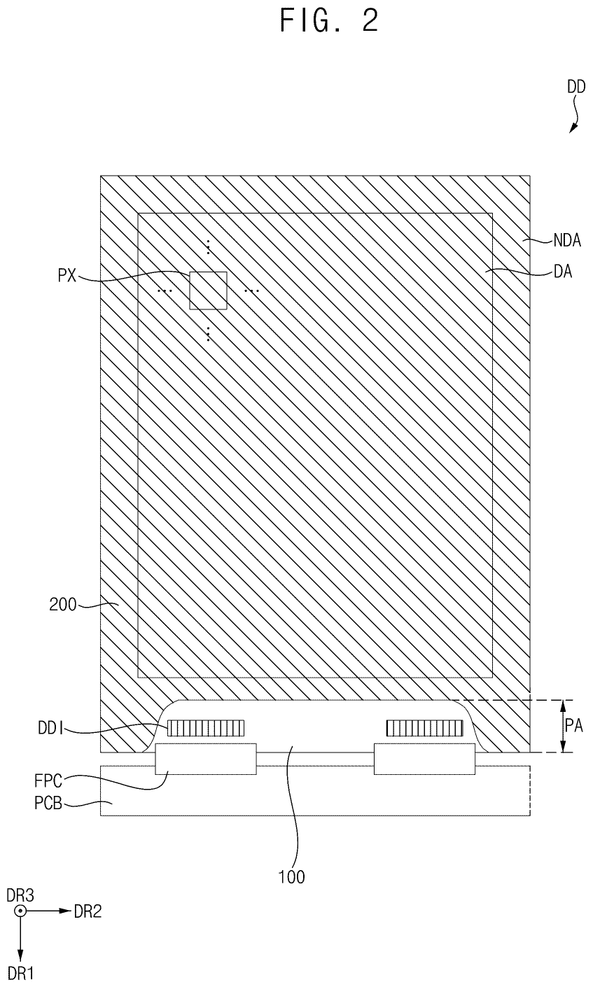

FIG. 1 is a plan view illustrating a display device DD according to an embodiment of the present disclosure. FIG. 2 is a plan view illustrating the display device DD of FIG. 1 with a cover member 300 omitted.

Referring to FIG. 1 and FIG. 2, a display device DD according to an embodiment of the present disclosure may include an array substrate 100 as a first substrate, an encapsulation layer 200, a driving chip DDI provided in plural including a plurality of driving chips DDI, a circuit board PCB, a flexible circuit film FPC, and a cover member 300.

The array substrate 100 may include a display area DA, a peripheral area NDA and a pad area PA.

A plurality of pixels PX may be arranged in the display area DA. Each of the plurality of pixels PX may emit light, such as for displaying an image at the display area DA. The plurality of pixels PX may be arranged in a matrix form. For example, the plurality of pixels PX may be arranged in a first direction DR1 and may be arranged in a second direction DR2 which crosses the first direction DR1. In an embodiment, the second direction DR2 may be perpendicular to the first direction DR1.

In this specification, a plane may be defined by the first direction DR1 and the second direction DR2 crossing each other. For example, the second direction DR2 may be perpendicular to the first direction DR1. In addition, a third direction DR3 may be perpendicular to the plane. A thickness of the display device DD and various components or layers thereof may be defined along the third direction DR3, e.g., a thickness direction of the array substrate 100.

The peripheral area NDA is adjacent to the display area DA, such as to surround the display area DA. The peripheral area NDA as a non-display area may include a planar area of the array substrate 100 except for a planar area of the display area DA. That is, the non-display area may be a remaining planar area of the array substrate 100 except for the display area. The pad area PA may be considered a portion of the non-display area, without being limited thereto.

A driving unit such a pixel circuit for driving the plurality of pixels PX may be disposed in the peripheral area NDA. The driving unit may be electrically connected to the plurality of pixels PX and provide a driving signal as an electrical signal to the plurality of pixels PX. The plurality of pixels PX may emit light with a brightness corresponding to the intensity of the driving signal. Accordingly, an image may be displayed in the display area DA by the light emitted from each of the plurality of pixels PX.

In an embodiment, the driving unit may include a gate driving unit. In an embodiment, the driving unit may include a light emission control driving unit.

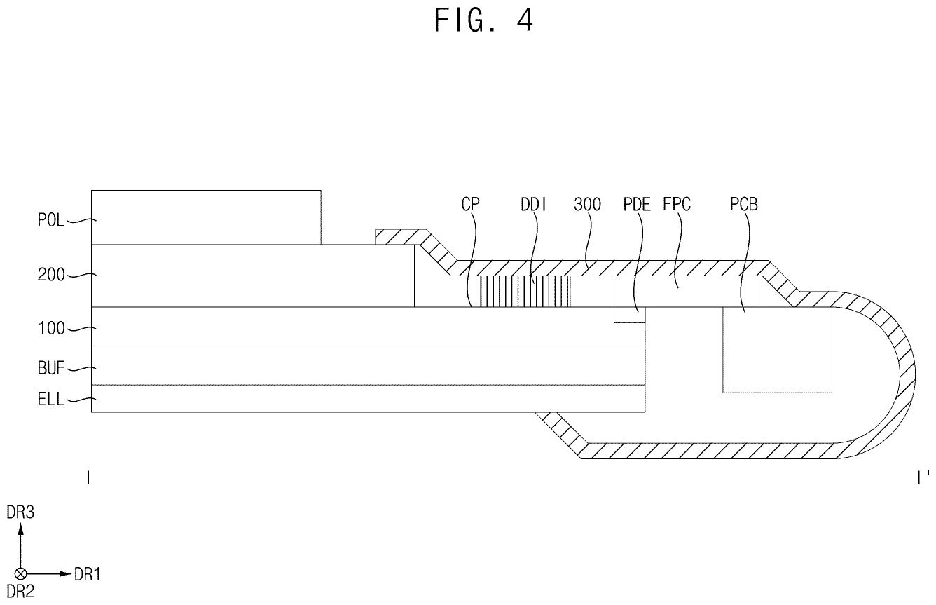

The pad area PA may be adjacent to the peripheral area NDA. The pad area PA may be spaced apart from one side of the display area DA, in the first direction DR1. A pad electrode PDE (of FIG. 4) may be disposed in the pad area PA. The pad electrode PDE may be electrically connected to the plurality of pixels PX.

The encapsulation layer 200 may be disposed on the array substrate 100, such as to face the array substrate 100 along the thickness direction. For example, the encapsulation layer 200 may overlap the display area DA and at least a portion of the peripheral area NDA which is adjacent to the display area DA. The encapsulation layer 200 may cover the plurality of pixels PX. The encapsulation layer 200 may protect the plurality of pixels PX from moisture and impurities.

The plurality of driving chips DDI may be disposed on the array substrate 100. The plurality of driving chips DDI may be disposed in the pad area PA. The plurality of driving chips DDI may be electrically connected to the plurality of pixels PX and the pad electrode PDE. The plurality of driving chips DDI may generate driving signals as electrical signals for driving the plurality of pixels PX.

In an embodiment, the plurality of driving chips DDI may be arranged in a row along the second direction DR2. Although two of the driving chips DDI are shown in FIG. 1 and FIG. 2, the number of the driving chips DDI is not limited thereto. That is, the display device DD may include two or more the driving chips DDI.

The circuit board PCB may be adjacent to the pad area PA. For example, as shown in FIG. 1 and FIG. 2, the circuit board PCB may be arranged to be spaced apart from the array substrate 100 the first direction DR1. Where the array substrate 100 represents a planar area of a display panel, the circuit board PCB may be considered an external component relative to the display panel, within the overall display device DD. However, the present disclosure is not limited to this, and the circuit board PCB may be placed below the array substrate 100, such as to overlap the array substrate 100 instead of being spaced apart from.

The flexible circuit film FPC may be electrically connected to the array substrate 100 at the pad area PA thereof, and to the circuit board PCB. For example, the flexible circuit film FPC may be connected to the array substrate 100 at one side (e.g., a first side of the flexible circuit film FPC) and to a circuit board PCB at the other side opposite to the one side (e.g., a second side of the flexible circuit film FPC which is opposite to the first side). Specifically, the flexible circuit film FPC may be electrically connected to the array substrate 100 at the pad electrode PDE. Accordingly, the flexible circuit film FPC may electrically connect the array substrate 100 and the circuit board PCB to each other.

The structure and location of the flexible circuit film FPC and the circuit board PCB may be described in more detail later with reference to FIGS. 4, 5, 6, and 7.

The cover member 300 may cover an upper surface of the display device DD facing the third direction DR3 and a portion of a back surface which is opposite to the upper surface. For example, the cover member 300 may cover a portion of the peripheral area NDA which is between the display area DA and the pad area PA, and the upper and rear surfaces of components of the display device DD which are overlapping with the pad area PA. The cover member 300 may be configured to be directly visible to outside the display device DD, such as to users thereof. The cover member 300 may provide an outer surface of the display device DD, together with other outermost surfaces defined by layers or components of the display device DD other than the cover member 300, without being limited thereto.

In an embodiment, the cover member 300 may contact the driving chips DDI. As being in contact, elements may be in physical contact such as to form an interface therebetween. Specifically, the cover member 300 may contact a portion of an upper surface of the encapsulation layer 200 and an upper surface of the driving chips DDI, and may extend from the driving chips DDI to cover the flexible circuit film FPC and the circuit board PCB of the display device DD which are attached to the array substrate 100. Accordingly, the cover member 300 may be fixed to a contact surface of the encapsulation layer 200 and may commonly protect the driving chips DDI, the flexible circuit film FPC and circuit board PCB from impact.

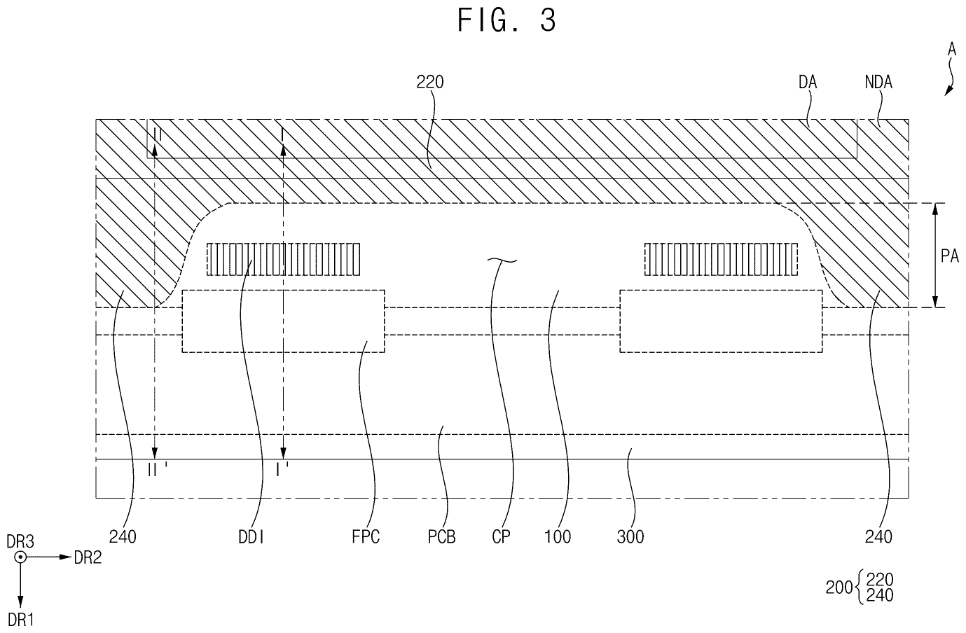

The configurations of the encapsulation layer 200 contacting the cover member 300 may be a portion of the base portion 220 (e.g., a main portion or main area in FIG. 3) overlapping with the display area DA and the peripheral area NDA, and convex portions 240 (e.g., a protruded portion provided in plural each of which extends from the main portion and in the first direction DR1 which protrude from the base portion toward the pad area PA. The explanation of base portion 220 and the convex portions 240 will be described in more detail later in FIG. 3.

In an embodiment, the cover member 300 may be spaced apart from an upper surface of the array substrate 100. Specifically, the cover member 300 may not contact the upper surface of the array substrate 100 which is adjacent to the driving chips DDI along a plane (e.g., a plane defined by the first and second directions DR1 and DR2 crossing each other).

FIG. 3 is an enlarged plan view of area A of FIG. 1. The area A may be an end portion of the display device DD.

Referring to FIGS. 1, 2, and 3, the encapsulation layer 200 may include the base portion 220, and the convex portions 240 which extends from the base portion 220. A boundary may be defined between the base portion 220 and the convex portion 240, and may extend along the second direction DR2. The base portion 220 may overlap the display area DA and extend from the display area DA to overlaps at least a portion of the peripheral area NDA. That is, the base portion 220 may be one unitary (or continuous) portion of the encapsulation layer 200 which does not overlap the pad area PA (e.g., except for the pad area PA). For example, the base portion 220 may overlap an entirety of the display area DA and an entirety of the the peripheral area NDA except for the pad area PA.

Each convex portion 240 among the convex portions 240 may protrude from the base portion 220, in a direction toward the pad area PA. The convex portions 240 may be formed integrally through the same process as the base portion 220, such as to provide the encapsulation layer 200 as a single body. That is, while the base portion 220 and the convex portions 240 effectively define one portion of the encapsulation layer 200 which does not overlap with the pad area PA and another portion which does overlap with the pad area PA, the two portions do not define a disconnection of the configuration.

In an embodiment, the thickness of the convex portions 240 and the base portion 220 may be the substantially equal along the thickness direction (e.g., the third direction DR3). However, the present disclosure is not limited thereto.

In an embodiment, the convex portions 240 may be spaced apart from the driving chips DDI on a plane. Specifically, the convex portions 240 may not contact upper surfaces of the driving chips DDI.

In FIG. 3, the number of the convex portions 240 are shown as two, but the present disclosure is not limited thereto. The number of the convex portions 240 may be three or more. The base portion 220 (and the pad area PA) may have a first end and a second end opposing each other along the second direction DR2. In addition, the convex portions 240 may be disposed respectively protruded from the base portion 220 at both of the opposing ends of the pad area PA. The convex portions 240 may be spaced apart from each other within the pad area PA, along the second direction DR2. However, the present disclosure is not limited thereto, and the positions of the convex portions 240 may be arranged in various positions on the pad area PA which do not overlap the driving chips DDI.

A concave portion CP may be defined along the plane of the array substrate 100 by the base portion 220 together with the convex portions 240. Specifically, the concave portion CP may be an area (e.g., a planar area) surrounded by base portion 220, outer surfaces of the convex portions 240, and an end of the array substrate 100 where the flexible circuit film FPC is connected. That is, the concave portion CP may be a virtual planar area where the upper surface of the array substrate 100 is exposed to outside the encapsulation layer 200 within the pad area PA. The concave portion CP may be defined by a recess of the encapsulation layer 200 which is open in the first direction DR1 and exposes an upper surface of the array substrate 100 to outside the display device DD.

In an embodiment, the convex portions 240 may have a planar shape in which at least one portion has an edge which is rounded. Corresponding to the shape of the convex portions 240, the concave portion CP may also have a planar shape in which at least one portion is rounded. However, the present disclosure is not limited thereto.

In an embodiment, the driving chips DDI may all be disposed within the concave portion CP. Although only one of the concave portion CP is shown in FIG. 3, the number of concave portion CP is not limited thereto. There may be one or more concave portions CP respectively defined between adjacent convex portions 240. For example, as shown in FIGS. 11 and 12, the number of the concave portion CP may be two or three.

In an embodiment, the convex portions 240 may extend to the end of the array substrate 100. For example, the convex portions 240 may cover an end portion of the array substrate 100 at the pad area PA. A distal end of the convex portion 240 may be aligned with a distal end of the array substrate 100 at the pad area PA. End surfaces of the convex portions 240 and the end surface of the array substrate 100 may be coplanar with each other without being limited thereto. Accordingly, the thickness of the display device DD may increase in the pad area PA, owing to the multilayer structure including the convex portions 240 overlapping the pad area PA. Accordingly, cracks occurring in the array substrate 100 from external impact may be reduced or prevented.

However, in FIG. 1, the convex portions 240 are shown to be formed up to a boundary of the pad area PA at the opposing ends thereof along the second direction DR2, but the present disclosure is not necessarily limited thereto. For example, the convex portions 240 may terminate before the boundary of the pad area PA, to be spaced apart from the pad area PA along the second direction DR2.

The cover member 300 may contact the upper surface of the encapsulation layer 200 at each of the convex portions 240 thereof, and a portion of the encapsulation layer 200 at the base portion 220 which overlaps the peripheral area NDA. That is, as the encapsulation layer 200 includes the convex portions 240, the cover member 300 may contact the encapsulation layer 200 even in the pad area PA. Accordingly, a total contact surface where the cover member 300 contacts the encapsulation layer 200 is expanded, so the lifting phenomenon of the cover member 300 within the display device DD may be reduced or prevented. Accordingly, durability of the display device DD may be improved.

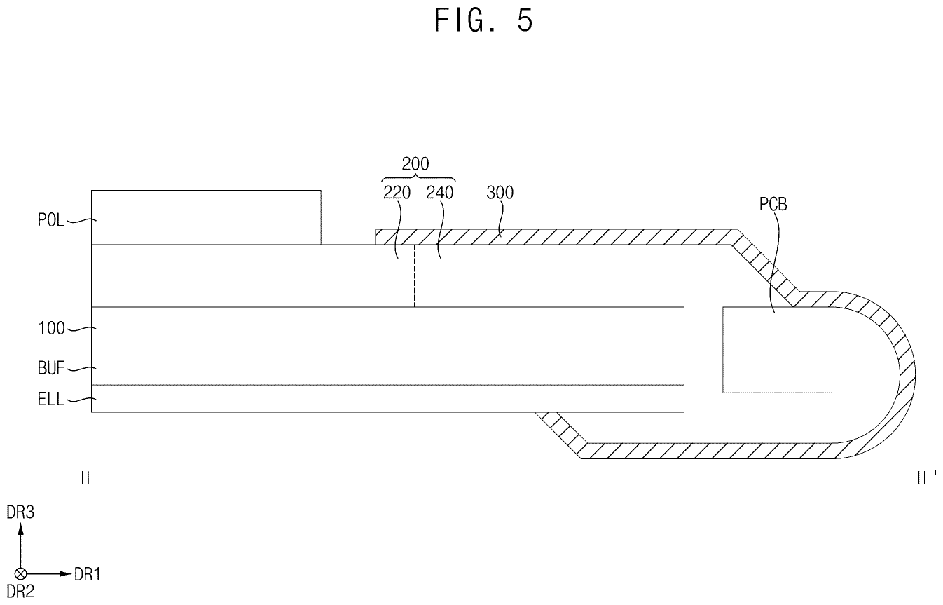

FIG. 4 is a cross-sectional view taken along line I-I′ of FIG. 3. FIG. 5 is a cross-sectional view taken along line II-II′ of FIG. 3.

Specifically, FIGS. 4 and 5 are views illustrating an example in which the circuit board PCB is spaced apart from the array substrate 100 in the first direction DR1 since the flexible circuit film FPC is not bent and/or does not have flexibility. That is, the circuit board PCB may be coplanar with a display panel of the display device DD. The circuit board PCB may be coplanar with the encapsulation layer 200 and the driving chips DDI.

Referring further to FIGS. 4 and 5, the display device DD may further include a polarization layer POL, a cushion layer BUF, an electrified layer ELL, and the pad electrode PDE. For convenience of explanation, various layers on the array substrate 100, either above or below along the third direction DR3, may define a display panel. For purposes of explanation, an end or boundary of the display area DA may correspond to an end of the polarization layer POL which is furthest in the first direction DR1. Boundaries of the pad area PA may correspond to the boundary between the base portion 220 and the convex portion 240 and the end of the encapsulation layer 200 which is furthest in the first direction DR1.

The polarization layer POL may be disposed on the encapsulation layer 200. For example, the polarization layer POL may cover at least a portion of the upper surface of the encapsulation layer 200. In addition, the polarization layer POL may be spaced apart from the cover member 300. In addition, the polarization layer POL may prevent external light incident from outside of the display device DD from being reflected inside the display device DD and being visible to the users. The polarization layer POL may define an upper surface of the display device DD (or of the display panel).

The cushion layer BUF may be disposed under the array substrate 100. The cushion layer BUF may include an insulating material. The cushion layer BUF may protect the array substrate 100 from impact. In addition, the cushion layer BUF may protect the array substrate 100 from moisture and impurities.

The electrified layer ELL may be disposed under the cushion layer BUF. The electrified layer ELL may include a conductive material to define a conductive layer. For example, the electrified layer ELL may include aluminum or copper. Each of the array substrate 100, the encapsulation layer 200, and the polarization layer POL which are disposed on the electrified layer ELL may have flexibility. The array substrate 100, the encapsulation layer 200, and the polarization layer POL may be flexed together with each other, such as to be bendable, foldable, rollable, etc.

Each of the array substrate 100, the encapsulation layer 200, the polarization layer POL and the electrified layer ELL may have a rigidity. The electrified layer ELL may have relatively greater rigidity than each of the array substrate 100, the encapsulation layer 200 and the polarization layer POL. In addition, the electrified layer ELL which has the higher rigidity, may support the array substrate 100, the encapsulation layer 200 and the polarization layer POL.

As described above, the pad electrode PDE may be disposed in the pad area PA of the array substrate 100. The pad electrode PDE may be within a cross-section and/or a planar area of the array substrate 100 and exposed to outside thereof. In addition, the pad electrode PDE may be connected to the flexible circuit film FPC. That is, the array substrate 100 may be connected to the flexible circuit film FPC through the pad electrode PDE. In addition, the array substrate 100 and the circuit board PCB may be connected through a flexible circuit film FPC.

The driving chips DDI may be spaced apart from the flexible circuit film FPC, in the first direction DR1. The driving chips DDI may be mounted to the array substrate 100, at the pad area PA the form of a chip on glass (COG) or a chip on plastic (COP). However, the present disclosure is not limited thereto.

The circuit board PCB may be spaced apart from end surfaces of each of the array substrate 100, the cushion layer BUF, and the electrified layer ELL, in a planar direction. In this case, the cover member 300 may contact a portion of the circuit board PCB. For example, the cover member 300 may contact an upper surface of the circuit board PCB and/or a portion of a side surface of the circuit board PCB which is disposed facing the first direction DR1.

In an embodiment, the cover member 300 may cover at least one of a flexible circuit film FPC and a circuit board PCB which are connected to the array substrate 100. Specifically, the cover member 300 may extend along an upper surface of the flexible circuit film FPC, along the upper surface of the circuit board PCB, and along the side surface of the circuit board PCB which faces the first direction DR1.

In an embodiment, the cover member 300 may contact the driving chips DDI. In this case, as shown in FIG. 4, one part (e.g., a first portion) of the cover member 300 contacting a portion of the encapsulation layer 200 and another part (e.g., a second portion) of the cover member 300 contacting the driving chips DDI, may form a step in the cross section. That is, the one part of the cover member 300 and the other part of the cover member 300 may be located at different levels with reference to the array substrate 100, that is, in different planes from each other. However, the present disclosure is not limited thereto. For example, the cover member 300 may contact only a portion of the upper surfaces of the driving chips DDI or may not contact the driving chips DDI.

As shown in FIG. 5, the cover member 300 may contact a portion of the base portion 220 and the convex portions 240. Specifically, the cover member 300 may contact only a portion of the upper surface of the base portion 220 and may be spaced apart from the polarization layer POL in the first direction DR1. In addition, the cover member 300 may contact all of the upper surfaces of the convex portions 240.

The cover member 300 may contact the upper surface of the circuit board PCB. Accordingly, one portion of the cover member 300 contacting a portion of the encapsulation layer 200 and another part of the cover member 300 contacting the circuit board PCB may form a step in the cross section. That is, the one part of the cover member 300 and the other part of the cover member 300 may be located at different levels from each other. However, the invention is not limited thereto.

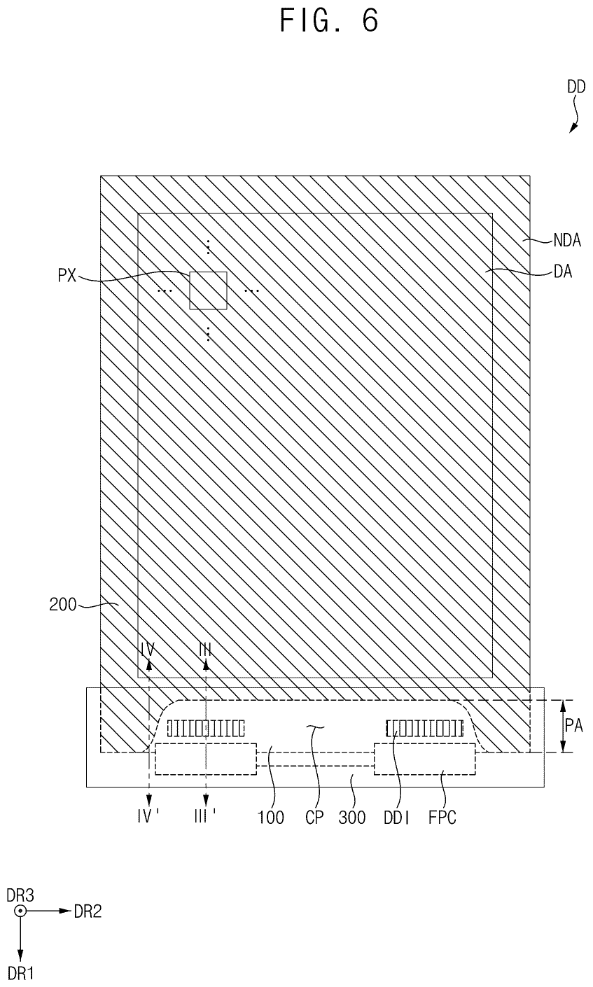

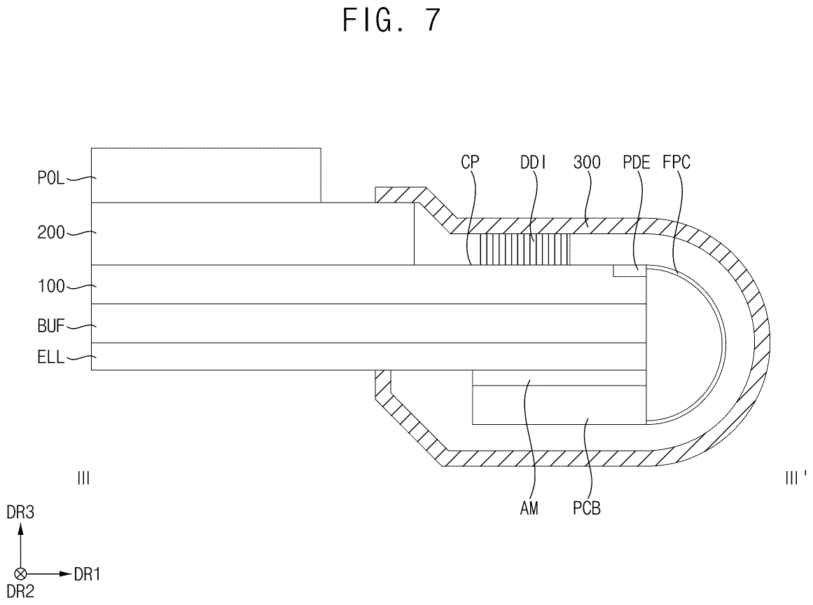

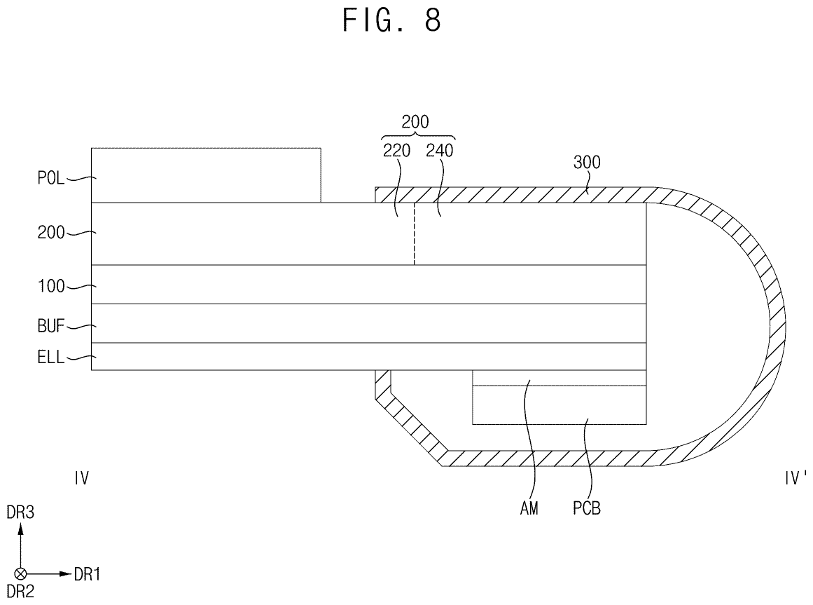

FIG. 6 is a plan view illustrating an example of the display device DD of FIG. 1 which is bent to define an end portion of the display device DD. FIG. 7 is a cross-sectional view taken along line III-III′ of FIG. 6. FIG. 8 is a cross-sectional view taken along line IV′-IV′ of FIG. 6.

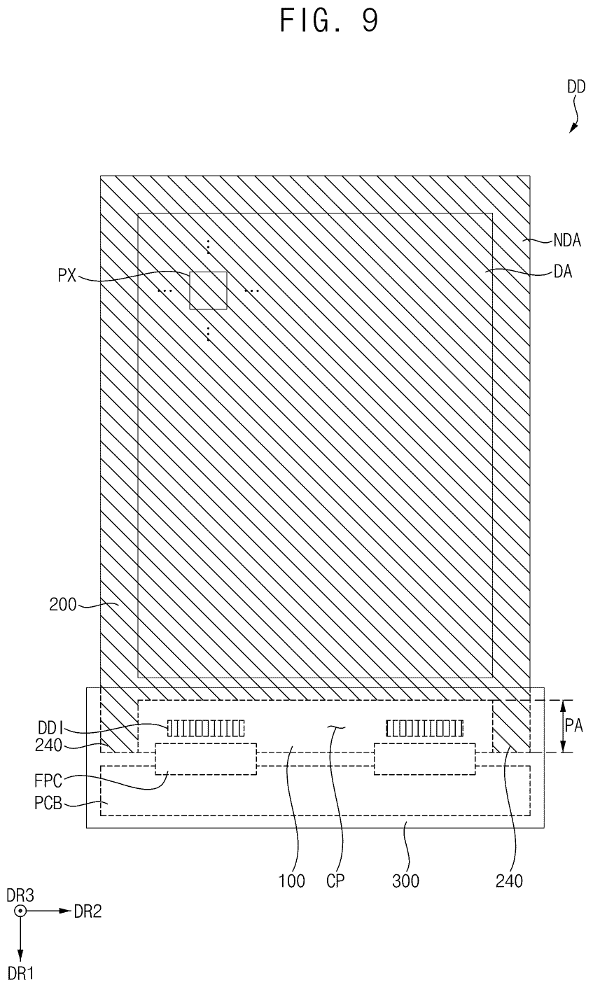

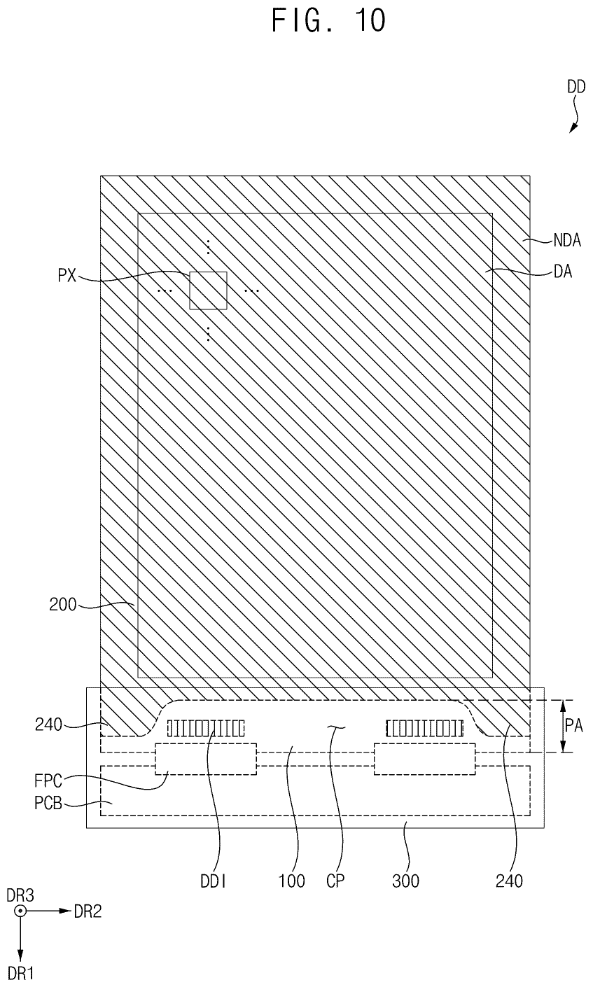

FIG. 9, FIG. 10, FIG. 11, and FIG. 12 are plan views illustrating various examples of the display device DD of FIG. 1.

Specifically, FIGS. 6, 7, and 8 are views illustrating an example in which the circuit board PCB is placed under the array substrate 100 by bending of the flexible circuit film FPC which has flexibility.

Referring to FIGS. 6 and 7, the circuit board PCB may be disposed under the electrified layer ELL. Specifically, the circuit board PCB may be electrically connected to the array substrate 100 through the flexible circuit film FPC having a curved surface. That is, the display device DD may be bent at the flexible circuit film FPC, and the display device DD which is bent includes the circuit board PCB may be disposed under the electrified layer ELL.

Referring to FIGS. 7 and 8, an adhesive member AM may be disposed between the circuit board PCB and the electrified layer ELL. For example, the circuit board PCB may be fixed to the lower part of the electrified layer ELL through the adhesive member AM. The adhesive member AM may include pressure sensitive adhesive (PSA), optical clear adhesive (OCA), photocurable resin, thermosetting resin, etc. These may be used alone or in combination with each other.

Referring to FIG. 9, in an embodiment, the convex portions 240 may have a rectangular planar shape. Corresponding to the shape of the convex portions 240, the concave portion CP may also have a rectangular planar shape. However, the present disclosure is not limited thereto, and the convex portions 240 and the concave portion CP may have various planar shapes. For example, as shown in FIG. 3, the convex portions 240 and the concave portion CP may have at least a portion of a rounded planar shape. That is, the encapsulation layer 200 may have a rounded edge at the convex portions 240.

As the convex portions 240 have various shapes, a contact surface where the cover member 300 and the encapsulation layer 200 contact each other in the pad area PA can be easily adjusted. Accordingly, case of design can be improved, and the lifting phenomenon of the cover member 300 can be further reduced or prevented.

Referring to FIG. 10, in an embodiment, distal ends (or distal edges) of the convex portions 240 may be disposed between the end surface of the array substrate 100 and the end surface of the base portion 220. Here, the ends, edge or surface may be furthest from the display area DA in a direction towards the pad area PA. In other words, the convex portions 240 may extend from the base portion 220 only to a specific point within the pad area PA, where the point is spaced apart from both the end surface of the base portion 220 and the end surface of the array substrate 100. That is, the convex portions 240 may not extend to the end of the array substrate 100, and a portion of the upper surface of the array substrate 100 may extend further than the distal ends of the convex portions 240 to be exposed to outside the encapsulation layer 200 at the distal ends of the convex portions 240.

However, although not shown in FIG. 10, the extent to which each of the plurality of convex portions 240 extends from the base portion 220 may be different. For example, one of the convex portions 240 (e.g., a first convex portion 240) may extend to the end of the array substrate 100, and another of convex portions 240 (e.g., a second convex portion 240 different from the first convex portion 240) may extend only to a specific point within the pad area PA.

According to embodiments, the degree to which the convex portions 240 extend from the base portion 220 may be adjusted in various ways, so that the contact surface where the cover member 300 and the encapsulation layer 200 contact each other in the pad area PA may be easily adjusted. Accordingly, case of design of the display device DD may be improved, and the lifting phenomenon of the cover member 300 may be further reduced or prevented.

Referring to FIG. 11, in an embodiment, at least one of the convex portions 240 may be located between driving chips DDI. Specifically, at least one of the convex portions 240 may be disposed between two adjacent driving chips DDI in a direction along the array substrate 100. In this case, at least one of the convex portions 240 disposed between the driving chips DDI may be spaced apart from each of the adjacent driving chips DDI.

The encapsulation layer 200 may be recessed at locations corresponding to the driving chips DDI, to define the concave portions CP. Each of the recesses may be open in a direction from the display area DA to the pad area PA.

As at least one of convex portions 240 is located between the driving chips DDI, the area of the convex portions 240 located in the pad area PA may further increase. That is, the contact surface where the cover member 300 and the encapsulation layer 200 contact each other in the pad area PA may be wider. Accordingly, the lifting phenomenon of the cover member 300 may be further reduced or prevented.

Referring to FIG. 12, in an embodiment, the driving chips DDI and the convex portions 240 may be arranged alternately with each other along the second direction DR2 on the plane of the array substrate 100. Specifically, one of the convex portions 240 may be located between two adjacent driving chips DDI. In addition, one of the driving chips DDI may be located between the convex portions 240 which are adjacent to each other. Accordingly, the contact surface which the cover member 300 and the encapsulation layer 200 contact each other in the pad area PA may be expanded, and the lifting phenomenon of the cover member 300 may be prevented or reduced.

However, the shape and arrangement of the convex portions 240 may be merely examples and may vary depending on the embodiments. For example, although not shown, in an embodiment including three or more driving chips DDI, one of the convex portions 240 may be disposed between a pair of adjacent driving chips DDI. In addition, the convex portions 240 may not be disposed between another pair of adjacent driving chips DDI. As another example, although not shown, at least two or more convex portions 240 may be disposed between a pair of adjacent driving chips DDI.

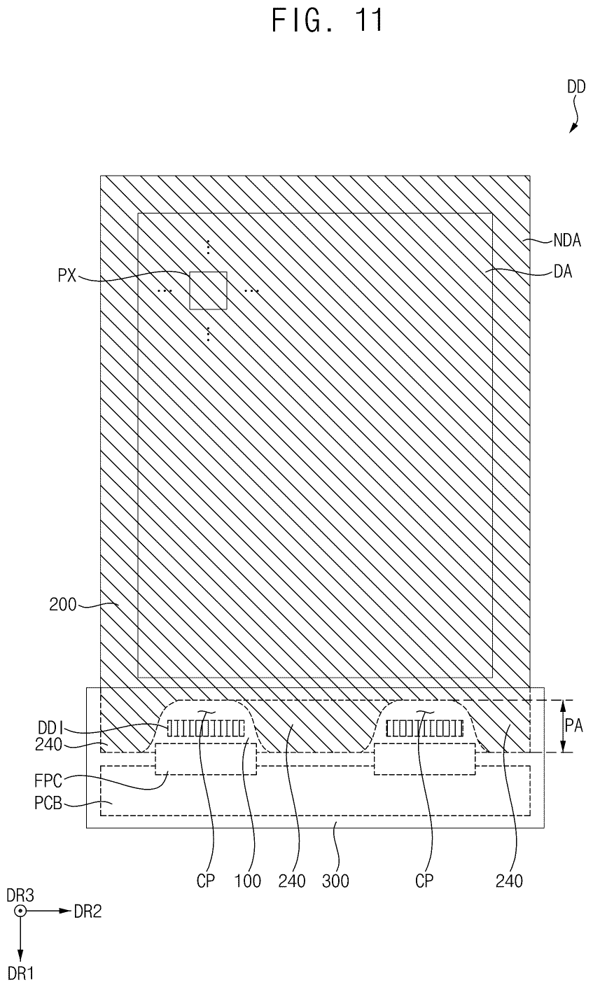

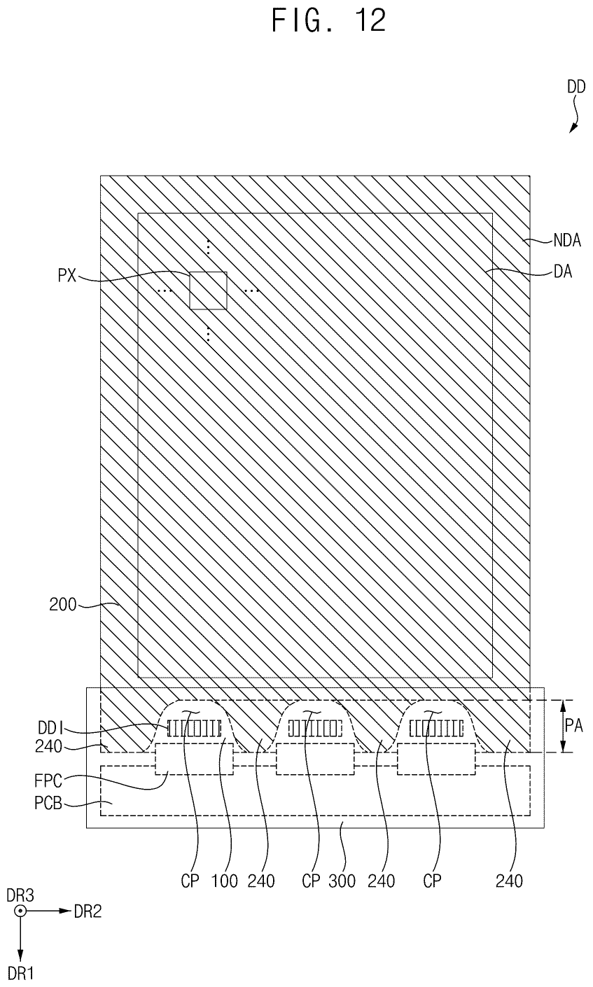

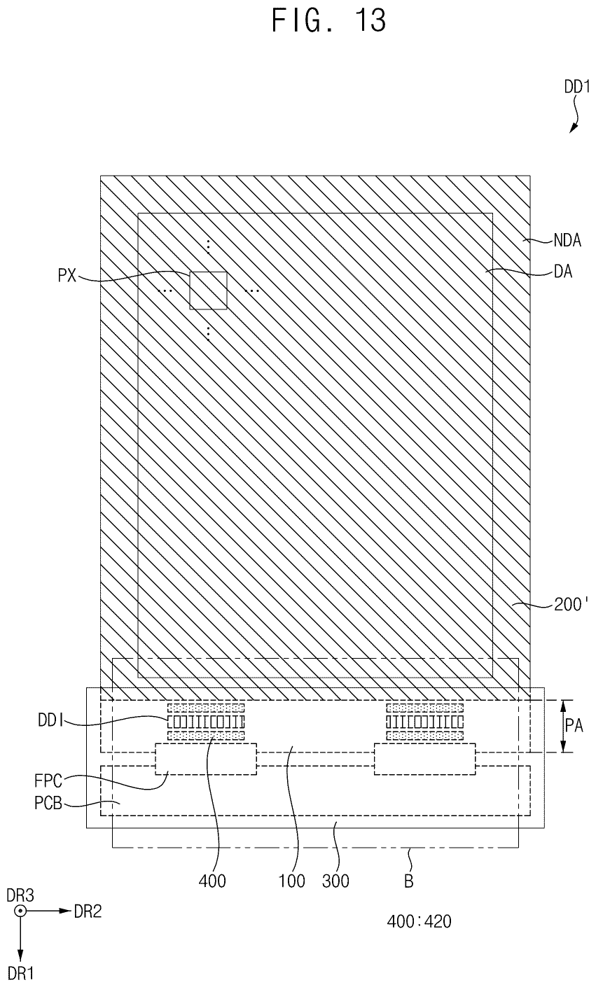

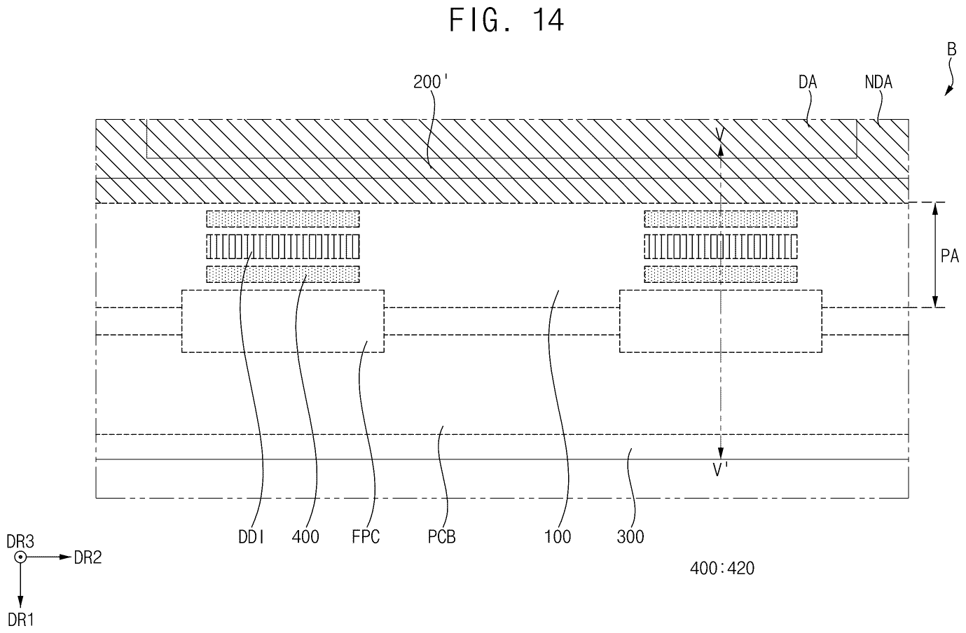

FIG. 13 is a plan view illustrating a display device DDI according to an embodiment of present disclosure. FIG. 14 is an enlarged view of area B of FIG. 13.

The display device DDI described with reference to FIGS. 13 and 14 may be substantially equal to the display device DD described with reference to FIGS. 1, 2, and 3 except that an encapsulation layer 200′ does not extend to the pad area PA and includes first reinforcing members 420. It may be substantially equal to Hereinafter, descriptions which overlap with the components of the display device DD described with reference to FIGS. 1, 2, and 3 will be omitted or simplified.

Referring to FIGS. 13 and 14, the encapsulation layer 200′ may be disposed on the display area DA and the peripheral area NDA of the array substrate 100. The encapsulation layer 200′ may be substantially equal to the encapsulation layer 200 described with reference to FIG. 1, except that it does not include convex portions 240 extended from the base portion 220. That is, the encapsulation layer 200′ may not extend to the pad area PA. For example, the encapsulation layer 200′ may have a configuration which substantially corresponds to the basc portion 220 of the encapsulation layer 200 of FIG. 1.

A reinforcing member 400 may be disposed on the pad area PA of the array substrate 100. The reinforcing member 400 may be provided in plural within the pad area PA. In an embodiment, the reinforcing member 400 which is provided in plural may include first reinforcing members 420 (e.g., first reinforcing patterns) of a reinforcing pattern layer. For example, the first reinforcing members 420 may be arranged to be spaced apart from the encapsulation layer 200′ in the first direction DR1 on the array substrate 100. The reinforcing member 400 may be disconnected from the encapsulation layer 200′.

In an embodiment, one of the driving chips DDI may correspond to at least two or more first reinforcing members 420. For example, as shown in FIG. 13, one of the driving chips DDI may correspond to a pair of first reinforcing members 420. The pair of first reinforcing members 420 corresponding to one of the driving chips DDI may be arranged to be spaced apart from each other, in the first direction DR1, with the corresponding driving chip DDI interposed therebetween. Specifically, one of the pair of first reinforcing members 420 may be disposed between the encapsulation layer 200′ and the corresponding driving chip DDI, and the other may be disposed between the corresponding driving chip DDI and the flexible circuit films FPC.

In an embodiment, the first reinforcing members 420 may include an adhesive material. For example, the adhesive material may include pressure sensitive adhesive (PSA), optical clear adhesive (OCA), photocurable resin, thermosetting resin, etc. These may be used alone or in combination with each other.

However, in FIGS. 13 and 14, the planar shape of the first reinforcing members 420 is shown to be rectilinear, but the planar shape of each of the first reinforcing members 420 may vary depending on the embodiments. The first reinforcing members 420 may be discrete patterns having a discrete planar shape in the plan view.

In an embodiment, the cover member 300 may contact a portion of the encapsulation layer 200′ in the peripheral area NDA, and may contact an upper surface of each of the first reinforcing members 420 in the pad area PA. That is, since the display device DD1 includes the first reinforcing members 420 disposed in the pad area PA, the cover member 300 may contact other components even in the pad area PA. Accordingly, the contact surface where the cover member 300 contacts other components on the array substrate 100 is expanded, so the lifting phenomenon of the cover member 300 may be reduced or prevented. Accordingly, the durability of the display device DDI may be improved.

However, the arrangement and number of the first reinforcing members 420 are merely examples and may vary depending on the embodiments. For example, although not shown, any one of the driving chips DDI may correspond to three or more first reinforcing members 420. Specifically, two or more first reinforcing members 420 corresponding to one driving chip DDI may be disposed between the encapsulation layer 200′ and the corresponding driving chip DDI. In addition, two or more first reinforcing members 420 corresponding to one driving chip DDI may be disposed between the flexible circuit film FPC and the corresponding driving chip DDI.

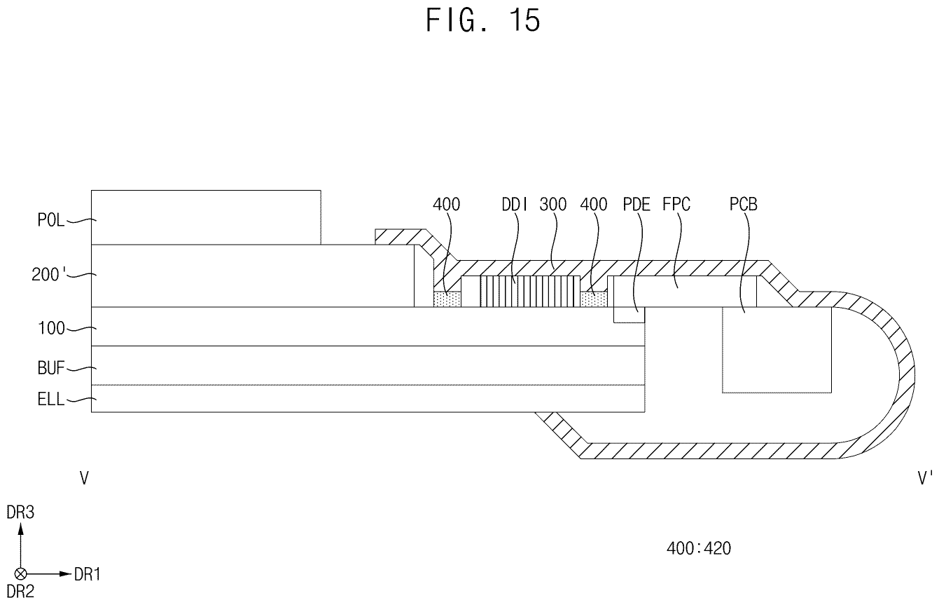

FIG. 15 is a cross-sectional view taken along line V-V′ of FIG. 14. FIG. 16 is a cross-sectional view along line V-V′ of FIG. 14.

The display device DDI described with reference to FIGS. 15 and 16 includes first reinforcing members 420, except that the cover member 300 further contacts the first reinforcing members 420. It may be substantially equal to the display device DD described with reference to FIG. 5.

Hereinafter, descriptions which overlap with the components of the display device DD described with reference to FIG. 4 will be omitted or simplified.

Referring to FIG. 15, in an embodiment, the thickness of the first reinforcing members 420 in the third direction DR3 may be smaller than the thickness of the driving chips DDI in the third direction DR3. In this case, the cover member 300 may have protruding surfaces (e.g., protrusions) to respectively contact the first reinforcing members 420. That is, a thickness of a portion of the cover member 300 at which the cover member 300 contacts the driving chip DDI, in the third direction DR3, and a thickness of a portion of the cover member 300 at which the cover member 300 contacts the first reinforcing members 420 may be different from each other. In addition, the cover member 300 may be spaced apart from the upper surface of the array substrate 100 at location where the first reinforcing members 420 are not disposed and the array substrate 100 is exposed to outside the first reinforcing members 420. In other words, the cover member 300 may not contact the upper surface of the array substrate 100 at which the first reinforcing members 420 are not disposed.

Referring to FIG. 16, in an embodiment, the thickness of the first reinforcing members 420 in the third direction DR3 may be substantially equal to the thickness of the driving chips DDI, in the third direction DR3. In this case, a surface of the cover member 300 contacting the first reinforcing members 420 and a surface contacting the driving chips DDI may be located at substantially equal level, that is, coplanar with each other. In this case, the cover member 300 may not include a separate protruding surface (or protrusion) for contacting the first reinforcing members 420. However, the present disclosure is not necessarily limited thereto, and when a thickness of the first reinforcing members 420 in the third direction DR3 is equal to the thickness of the driving chips DDI in the third direction DR3, the cover member 300 may have a separate protruding surface def.

However, in FIGS. 13, 14, 15, and 16, the description focuses on an example in which the flexible circuit film FPC does not have flexibility, the flexible circuit film FPC is extended flat (e.g., unbent), and the circuit board PCB is spaced apart from the array substrate 100 in the first direction DR1, the present disclosure is not necessarily limited thereto. For example, even in the display device DD1 including the first reinforcing members 420, the flexible circuit film FPC may have flexibility, as described with reference to FIGS. 6, 7, and 8, and the flexible circuit film FPC is bent. Accordingly, the circuit board PCB may be placed under the array substrate 100 by bending of the display device DD1 at the the flexible circuit film FPC.

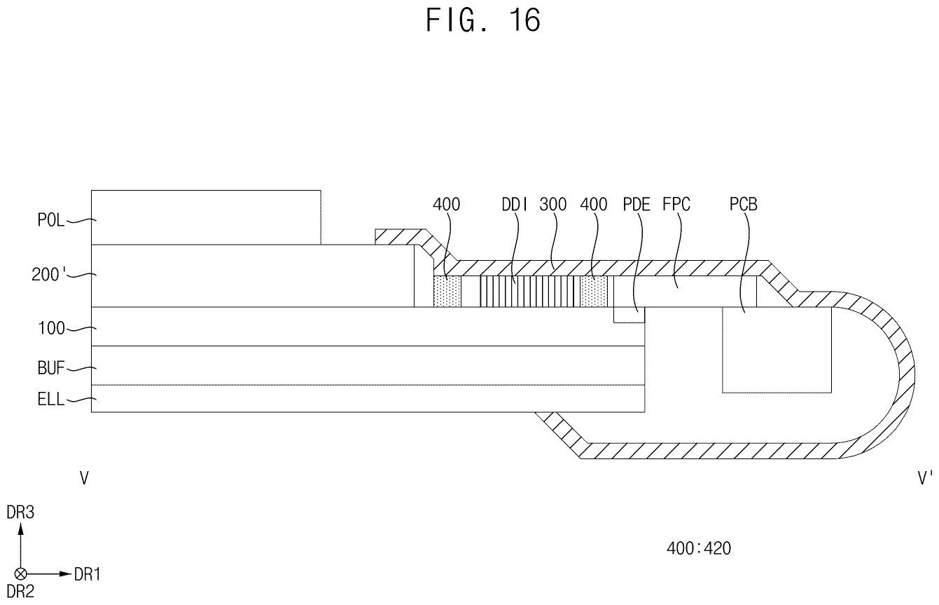

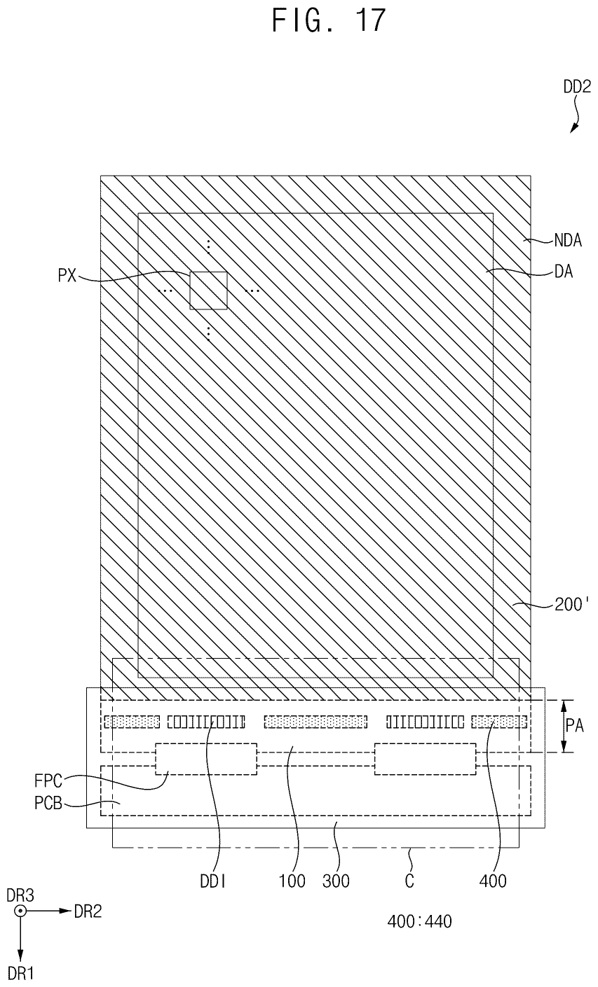

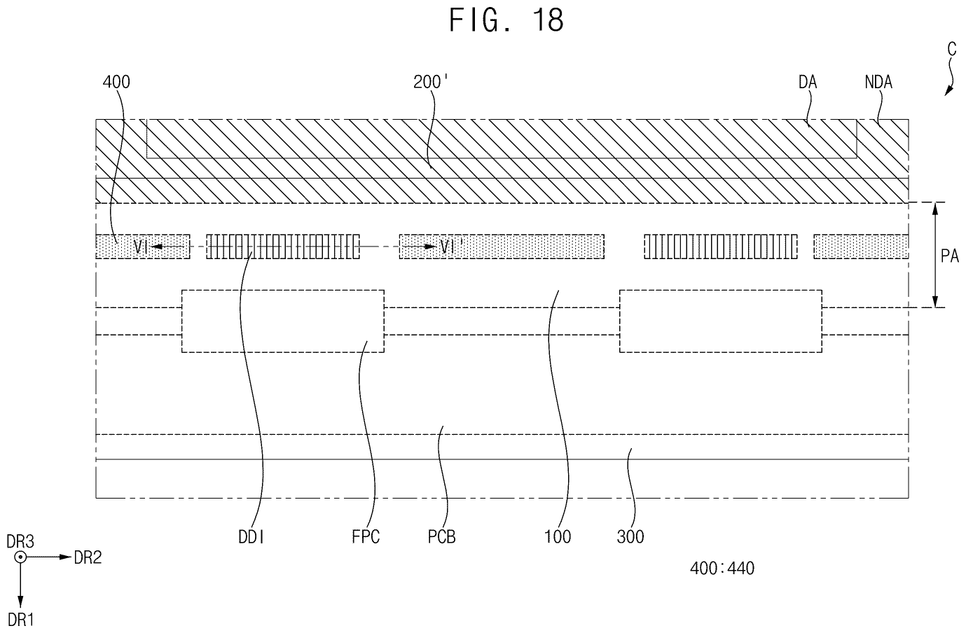

FIG. 17 is a plan view illustrating a display device DD2 according to an embodiment of present disclosure. FIG. 18 is an enlarged view of area C of FIG. 17.

The display device DD2 described with reference to FIGS. 17 and 18 may be substantially equal to the display device DD1 described with reference to FIGS. 13 and 14, except that it includes second reinforcing members 440 instead of the first reinforcing members 420.

Hereinafter, descriptions which overlap with the components of the display device DD1 described with reference to FIGS. 13 and 14 will be omitted or simplified.

Referring to FIGS. 17 and 18, the reinforcing member 400 may be provided in plural in the pad area PA of the array substrate 100. In an embodiment, the reinforcing member 400 may be provided in plural including the second reinforcing members 440 (e.g., second reinforcing patterns) of a reinforcing pattern layer. For example, the second reinforcing members 440 may be arranged spaced apart from each other in the second direction DR2 on the array substrate 100.

In an embodiment, one of the driving chips DDI may correspond to at least two second reinforcing members 440. For example, as shown in FIG. 17, one of the driving chips DDI may correspond to a pair of second reinforcing members 440. The pair of second reinforcing members 440 corresponding to one of the driving chips DDI may be arranged to be spaced apart from each other in the second direction DR2 with the corresponding driving chip DDI interposed therebetween. Specifically, one of the pair of second reinforcing members 440 may be arranged to be spaced apart from the corresponding driving chip DDI in the second direction DR2, and the other of the pair of second reinforcing members 440 may be arranged to be spaced apart from the corresponding driving chip DDI in a direction opposite to the second direction DR2.

In an embodiment, the second reinforcing members 440 may include an adhesive material. For example, the adhesive material may include pressure sensitive adhesive (PSA), optical clear adhesive (OCA), photocurable resin, thermosetting resin, etc. These may be used alone or in combination with each other.

However, in FIGS. 17 and 18, the planar shape of the second reinforcing members 440 is shown to be square, but the planar shape of each of the second reinforcing members 440 may vary depending on the embodiments.

In an embodiment, the cover member 300 may contact a portion of the encapsulation layer 200′ in the peripheral area NDA, and may contact an upper surface of each of the second reinforcing members 440 in the pad area PA. That is, since the display device DD2 includes the second reinforcing members 440 disposed in the pad area PA, the cover member 300 may contact other components of the display device DD2 which are on the array substrate 100, even in the pad area PA. Accordingly, a contact surface where the cover member 300 contacts other components on the array substrate 100 is expanded, so the lifting phenomenon of the cover member 300 may be reduced or prevented.

However, the arrangement and number of the second reinforcing members 440 are merely examples and may vary depending on the embodiments.

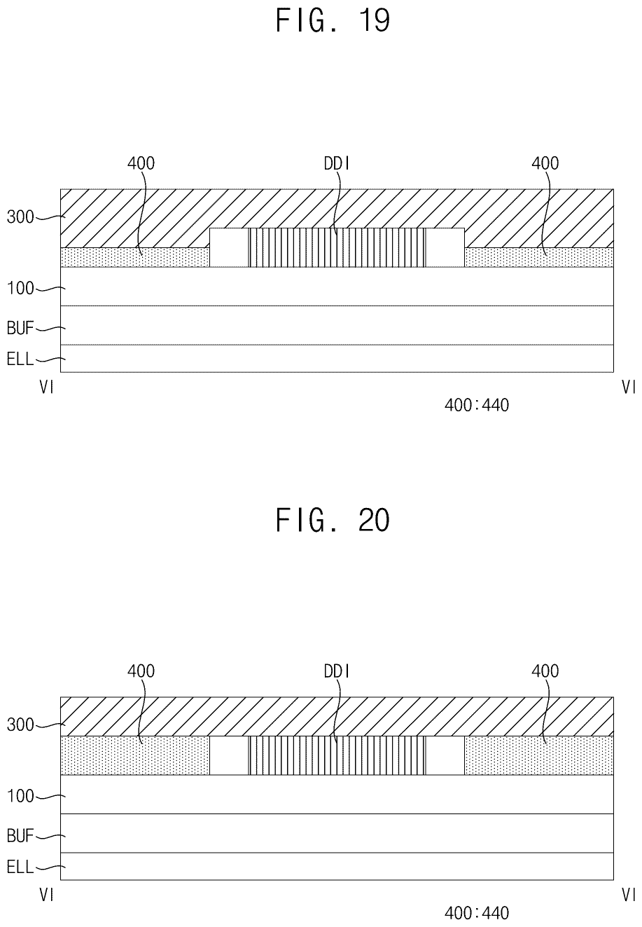

FIG. 19 is a cross-sectional view taken along line VI-VI′ of FIG. 14. FIG. 20 is a cross-sectional view taken along line VI-VI′ of FIG. 14.

Referring to FIG. 19, in an embodiment, a thickness of the second reinforcing members 440 in the third direction DR3 may be less than a thickness of the driving chips DDI in the third direction DR3. In this case, the cover member 300 may have protrusions to contact the second reinforcing members 440. That is, a thickness of a portion of the cover member 300 at which the cover member 300 contact the driving chips DDI in the third direction DR3, and a thickness of a portion of the cover member 300 at which the cover member 300 contacts the second reinforcing members 440, may be different. In addition, the cover member 300 may be spaced apart from the upper surface of the array substrate 100 which is closest to the cover member 300 along the third direction and at which the second reinforcing members 440 are not disposed. In other words, the cover member 300 may not contact the exposed upper surface of the array substrate 100 at which the second reinforcing members 440 are not disposed and at which the exposed upper surface is exposed to the cover member 300 along the third direction.

Referring to FIG. 20, in an embodiment, the thickness of the second reinforcing members 440 in the third direction DR3 may be substantially equal to the thickness of the driving chips DDI, in the third direction DR3. In this case, contact surfaces of the cover member 300 at which the cover member 300 contacts the second reinforcing members 440 and contact surfaces of the cover member 300 at which the cover member 300 contacts the driving chips DDI may be located at substantially equal level relative to a reference surface such as the upper surface of the array substrate 100 (e.g., coplanar with each other). In this case, the cover member 300 may not include a protruding surface for contacting the second reinforcing members 440. However, the present disclosure is not limited thereto, and even when a thickness of the second reinforcing members 440 in the third direction DR3 is equal to a thickness of the driving chips DDI in the third direction DR3, the cover member 300 may have a separate protruding surface defined by a protrusion of the cover member 300.

However, in FIGS. 17, 18, 19, and 20, the description focuses on an example in which the flexible circuit film FPC does not have flexibility and the circuit board PCB is spaced apart from the array substrate 100 in the first direction DR1, the present disclosure may not be necessarily limited thereto. For example, even in the display device DD2 including the second reinforcing members 440, the flexible circuit film FPC may have flexibility, as described with reference to FIGS. 6, 7, and 8. Accordingly, the circuit board PCB may be placed under the array substrate 100 within the display device DD2 which is bent or folded by bending of the flexible circuit film FPC.

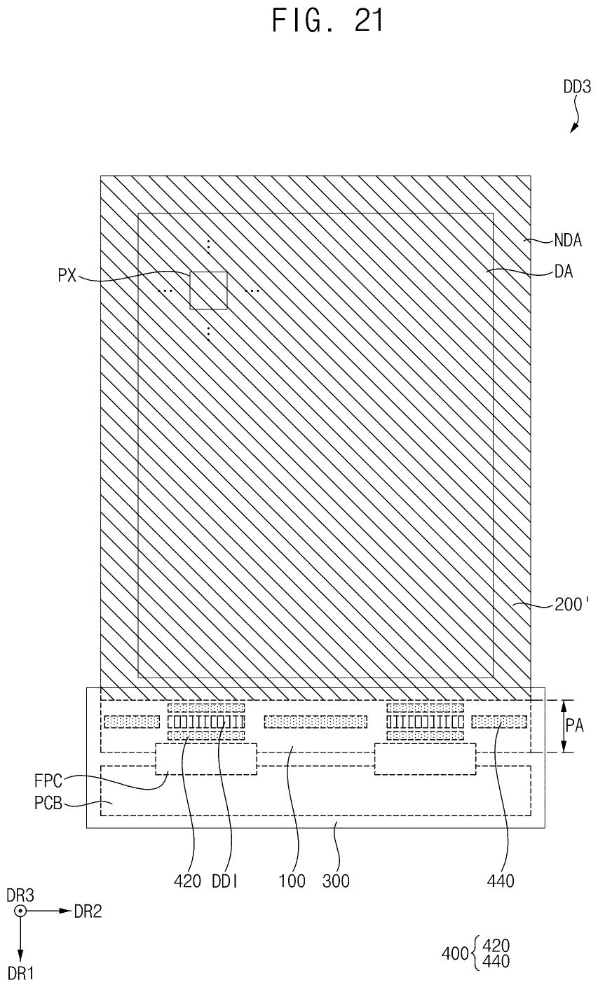

FIG. 21 is a plan view illustrating a display device DD3 according to an embodiment of present disclosure.

The display device DD3 described with reference to FIG. 21 may be substantially equal to the display device DD1 described with reference to FIGS. 13 and 14 except that it further includes second reinforcing members 440. Hereinafter, descriptions which overlap with the components of the display device DD1 described with reference to FIGS. 13 and 14 will be omitted or simplified.

Here, the second reinforcing members 440 may be substantially equal to explanation described with reference to FIGS. 17, 18, 19, and 20. Hereinafter, descriptions which overlap with those described with reference to FIGS. 17, 18, 19, and 20 will be omitted or simplified.

Referring to FIG. 21, the display device DD3 may include a reinforcing member 400 which is provided in plural. The reinforcing member 400 provided in plural may include the first reinforcing members 420 and the second reinforcing members 440 within a reinforcing layer. That is, the display device DD3 may simultaneously include the first reinforcing members 420 described with reference to FIGS. 13 and 14 and the second reinforcing members 440 described with reference to FIGS. 17 and 18. As the display device DD3 includes both the first reinforcing members 420 and the second reinforcing members 440, the lifting phenomenon of the cover member 300 may be further reduced or prevented.

The first reinforcing members 420 may be aligned with or correspond to a driving chip DDI, along the first direction DR1. The first reinforcing members 420 may be aligned with each other along the first direction DR1, without being limited thereto. Along the first direction DR1, the second reinforcing members 440 may correspond to gaps between driving chips DDI spaced apart from each other along the second direction DR2. Along the second direction DR2, within the pad area PA, the first reinforcing members 420 may alternate with the second reinforcing members 440.

In embodiments in which the display device DD3 includes both first reinforcing members 420 and second reinforcing members 440, the first reinforcing members 420 and the second reinforcing members 440 may contain the same materials as each other. A thickness of the first reinforcing members 420 in the third direction DR3 may be equal to a thickness of the second reinforcing members 440 in the third direction DR3. For example, the first reinforcing members 420 and the second reinforcing members 440 may be formed through the same process. A planar shape of each of the first reinforcing members 420 may be substantially equal to a planar shape of each of the second reinforcing members 440. For example, as shown in FIG. 21, the planar shape of each of the first reinforcing members 420 and the planar shape of each of the second reinforcing members 440 may both have a rectangular planar shape. The first reinforcing members 420 and the second reinforcing members 440 may be in a same layer of the display device DD3. As being in a same layer, elements may be formed in a same process and/or include a same material as each other, elements may be respective portions of a same material layer, elements may be on a same layer by forming an interface with a same underlying or overlying layer, etc., without being limited thereto.

However, in the present disclosure, the material, thickness, and shape of the first reinforcing members 420 and the second reinforcing members 440 may not be limited thereto. For example, the materials, thicknesses, and shapes of the first and second reinforcing members 420 and 440 of the display device DD3 may be different from each other.

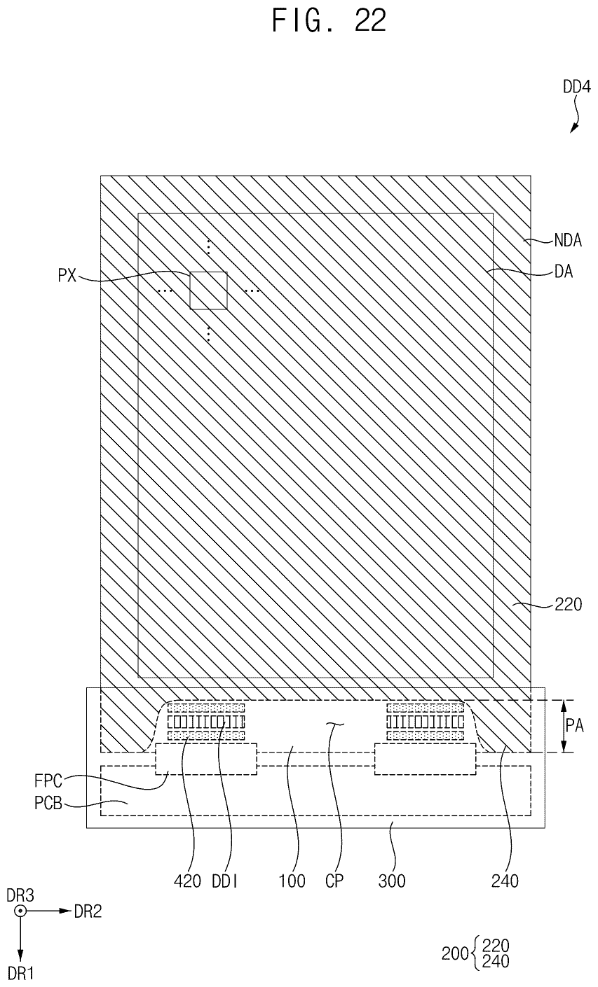

FIG. 22 is a plan view illustrating a display device DD4 according to an embodiment of present disclosure.

The display device DD4 described with reference to FIG. 22 may be substantially the equal to the display device DD described with reference to FIG. 1 except that it further includes first reinforcing members 420. Hereinafter, descriptions that overlap with the components of the display device DD described with reference to FIG. 1 will be omitted or simplified.

Here, the first reinforcing members 420 may be substantially the equal to explanation described with reference to FIG. 13. Hereinafter, descriptions which overlap with those described with reference to FIG. 13 will be omitted or simplified.

Referring to FIG. 22, the display device DD4 may include both the convex portions 240 and the first reinforcing members 420. In an embodiment, the first reinforcing members 420 may be disposed within the concave portion CP defined on the plane of the array substrate 100, together with the driving chips DDI.

The first reinforcing members 420 may be arranged to be spaced apart from the convex portions 240. In other words, each of the first reinforcing members 420 may not contact the convex portions 240 on the array substrate 100. As not being in contact, elements may be spaced apart from each or or adjacent to each other along a direction. For example, the first reinforcing members 420 which do not contact the convex portions 240 may be spaced apart from and/or adjacent to the convex portions 240 in one or more directions along the array substrate 100 (e.g., planar directions).

The cover member 300 may contact the upper surface of each of the portion of the base portion 220 of the encapsulation layer 200 which overlaps the peripheral area NDA, the convex portions 240 of the encapsulation layer 200, and the first reinforcing members 420. As the display device DD4 includes both the convex portions 240 and the first reinforcing members 420, the lifting phenomenon of the cover member 300 may be further reduced or prevented.

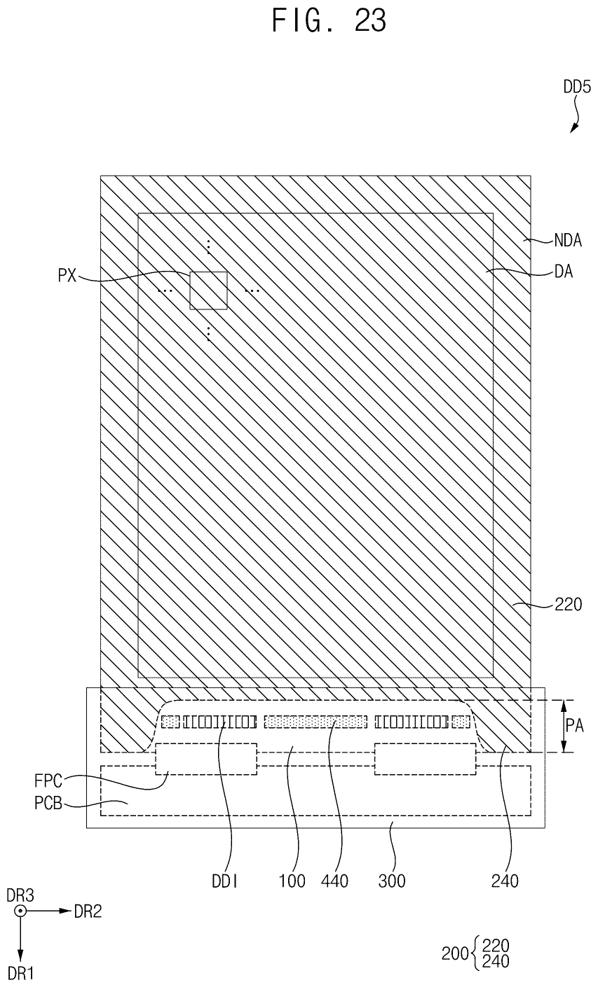

FIG. 23 is a plan view illustrating a display device DD5 according to an embodiment of present disclosure.

The display device DD5 described with reference to FIG. 23 may be substantially equal to display device DD4 described with reference to FIG. 22, except that it includes second reinforcing members 440 instead of the first reinforcing members 420. Hereinafter, descriptions which overlap with the components of the display device DD4 described with reference to FIG. 22 will be omitted or simplified.

Here, the second reinforcing members 440 may be substantially equal to explanation described with reference to FIG. 17. Hereinafter, descriptions which overlap with those described with reference to FIG. 17 will be omitted or simplified.

Referring to FIG. 23, the display device DD5 may include both convex portions 240 and second reinforcing members 440. In an embodiment, the second reinforcing members 440 may be disposed within the concave portion CP defined on the plane of the array substrate 100.

The second reinforcing members 440 may be arranged to be spaced apart from the convex portions 240. In other words, each of the second reinforcing members 440 may not contact the convex portions 240 on the array substrate 100.

The cover member 300 may contact a portion of the base portion 220 which overlaps the peripheral area NDA, the upper surfaces of each of the convex portions 240 and the second reinforcing members 440. As the display device DD5 includes both the convex portions 240 and the second reinforcing members 440, the lifting phenomenon of the cover member 300 can be further reduced or prevented.

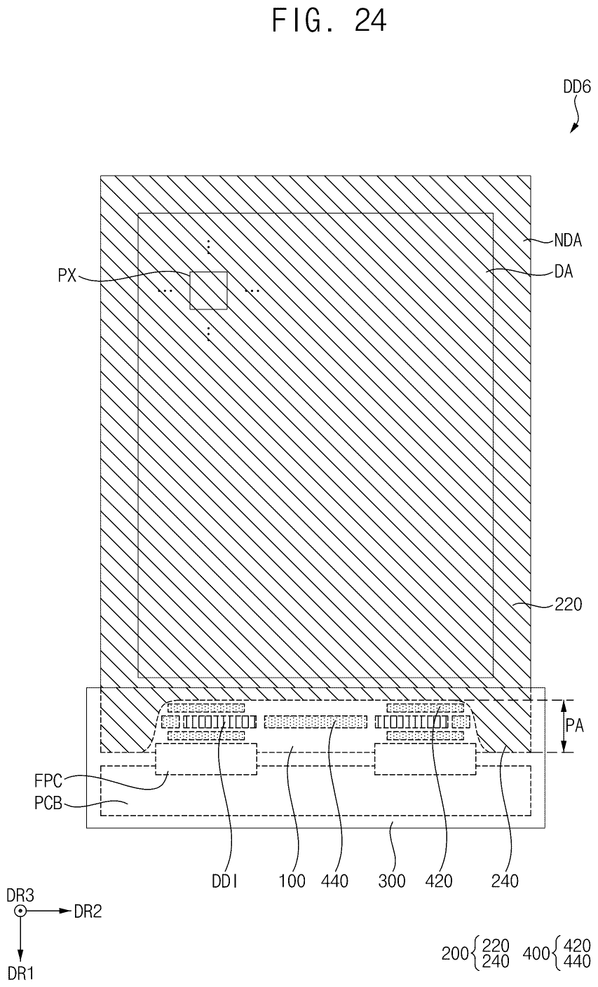

FIG. 24 is a plan view illustrating a display device DD6 according to an embodiment of present disclosure.

The display device DD6 described with reference to FIG. 24 may be substantially equal to the display device DD4 described with reference to FIG. 22 except which it further includes second reinforcing members 440. Hereinafter, descriptions which overlap with the components of the display device DD4 described with reference to FIG. 22 will be omitted or simplified.

Here, the second reinforcing members 440 may be substantially equal to explanation described with reference to FIG. 17. Hereinafter, descriptions which overlap with those described with reference to FIG. 17 will be omitted or simplified.

Referring to FIG. 24, the display device DD6 may include the convex portions 240, the first reinforcing members 420, and the second reinforcing members 440. In an embodiment, the first reinforcing members 420 and the second reinforcing members 440 may be disposed within the concave portion CP defined on the plane of the array substrate 100.

The first reinforcing members 420 and the second reinforcing members 440 may be arranged to be spaced apart from the convex portions 240. In other words, each of the first reinforcing members 420 and the second reinforcing members 440 may not contact the convex portions 240 on the array substrate 100.

The cover member 300 may contact an upper surface of each of a portion of the base portion 220 overlapping with the peripheral area NDA, the convex portions 240, the first reinforcing members 420, and the second reinforcing members 440. As the display device DD6 includes all of the convex portions 240, first reinforcing members 420, and second reinforcing members 440, the lifting phenomenon of the cover member 300 may be further reduced or prevented.

However, in FIGS. 22, 23, and 24, the description focuses on an example in which the flexible circuit film FPC does not have flexibility and the circuit board PCB is spaced apart from the array substrate 100 in the first direction DR1, the invention may not be necessarily limited thereto. For example, in the display devices DD4, DD5, and DD6 according to various embodiments described with reference to FIGS. 22, 23, and 24, as described with reference to FIGS. 6, 7, and 8, the flexible circuit film FPC may have flexibility. Accordingly, the circuit board PCB may be placed under the array substrate 100 by bending of the flexible circuit film FPC.

A display device DD according to various embodiments of the invention may include the convex portions 240 of an encapsulation layer 200 which extend from the peripheral area NDA to the pad area PA and/or the reinforcing member 400, within the pad area PA. Accordingly, since a thickness of the display device DD increases at the pad area PA, cracks occurring in the array substrate 100 may be reduced or prevented. In addition, the cover member 300 covering planar areas of the pad area PA may contact the convex portions 240 of the encapsulation layer 200 and/or the reinforcing member 400, within in the pad area PA. In addition, a contact surface at which the cover member 300 contacts other components on the array substrate 100 may be expanded. Accordingly, the lifting phenomenon of the cover member 300 from the underlying stacked structure including the array substrate 100, may be reduced or prevented. Accordingly, durability of the display device DD may be improved.

The display device DD according to the embodiments may be applied to a display device DD included in a computer, a notebook, a mobile phone, a smartphone, a smart pad, a PMP, a PDA, an MP3 player, or the like.

Although the display device DD according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
an array substrate comprising a display area including pixels, a peripheral area and a pad area, in order in a first direction;
driving chips on the array substrate, in the pad area, the driving chips arranged spaced apart from each other along a second direction intersecting the first direction;
an encapsulation layer on the array substrate and covering the pixels, the encapsulation layer comprising:
a base portion overlapping the display area and the peripheral area, and
convex portions protruding from a side of the base portion, in the first direction, the convex portions overlapping the pad area; and
a cover member covering the driving chips, in the pad area, the cover member contacting the convex portions of the encapsulation layer.

2. The display device of claim 1, wherein along a plane defined by the first and second directions intersecting each other, the driving chips and the convex portions are spaced apart from each other.

3. The display device of claim 1, wherein
the base portion together with the convex portions define a single concave portion of the encapsulation layer, and
the driving chips are all within the single concave portion of the encapsulation layer.

4. The display device of claim 1, wherein a convex portion among the convex portions is between the driving chips.

5. The display device of claim 1, wherein the convex portions and the driving chips are arranged alternately along the second direction.

6. The display device of claim 1, wherein the convex portions extend to an end of the array substrate which is furthest from the display area in the first direction.

7. The display device of claim 1, wherein the cover member contacts the driving chips.

8. The display device of claim 1, wherein along a thickness direction of the array substrate,
the array substrate includes an upper surface closest to the cover member, and
the cover member is spaced apart from the upper surface of the array substrate.

9. The display device of claim 1, further comprising a reinforcing member on the array substrate, in the pad area,
wherein
the base portion together with the convex portions define a concave portion of the encapsulation layer,
the reinforcing member is within the concave portion of the encapsulation layer, and
the cover member further contacts the reinforcing member, in the pad area.

10. The display device of claim 9, wherein along a plane defined by the first and second directions intersecting each other, the reinforcing member is spaced apart from the driving chips.

11. The display device of claim 9, wherein the reinforcing member includes first reinforcing patterns spaced apart from each other along the first direction with a driving chip among the driving chips therebetween.

12. The display device of claim 9, wherein the reinforcing member includes second reinforcing patterns spaced apart from each other in the second direction with a driving chip among the driving chips therebetween.

13. The display device of claim 9, wherein the reinforcing member includes an adhesive material.

14. The display device of claim 1, further comprising:
a circuit board electrically connected to the array substrate; and
a flexible circuit film which electrically connects the circuit board to the array substrate, the flexible circuit film electrically connected to the array substrate at the pad area thereof,
wherein the cover member which covers the pixels extends from the display area to cover the flexible circuit film or the circuit board.

15. A display device comprising:
an array substrate comprising a display area including pixels, a peripheral area and a pad area, in order in a first direction;
driving chips on the array substrate, in the pad area, the driving chips arranged spaced apart from each other along a second direction intersecting the first direction;
an encapsulation layer on the array substrate and covering the pixels;
a reinforcing member on the array substrate, in the pad area, the reinforcing member spaced apart from each of the encapsulation layer and the driving chips; and
a cover member covering the driving chips, in the pad area, the cover member contacting the reinforcing member.

16. The display device of claim 15, wherein along a plane defined by the first and second directions intersecting each other, the reinforcing member is spaced apart from the driving chips.

17. The display device of claim 15, wherein the reinforcing member includes first reinforcing patterns spaced apart from each other along the first direction with a driving chip among the driving chips therebetween.

18. The display device of claim 15, wherein the reinforcing member includes second reinforcing patterns spaced apart from each other along the second direction with a driving chip among the driving chips therebetween.

19. The display device of claim 15, wherein the reinforcing member includes an adhesive material.

20. The display device of claim 15, further comprising:
a circuit board electrically connected to the array substrate; and
a flexible circuit film which electrically connects the circuit board to the array substrate, the flexible circuit film electrically connected to the array substrate at the pad area thereof,
wherein the cover member which covers the pixels extends from the display area to cover the flexible circuit film or the circuit board.
